(19) United States
(12) Patent Application Publication
(10) Pub. No.: US 2012/0148763 A1
(43) Pub. Date: Jun. 14, 2012

(54) SURFACE WAVE PLASMA CVD APPARATUS AND LAYER FORMATION METHOD

(75) Inventor: Masayasu Suzuki, Atsugi-shi (JP)

(73) Assignee: SHIMADZU CORPORATION, Kyoto-shi, Kyoto (JP)

(21) Appl. No.: 13/392,408

(22) PCT Filed: Oct. 4, 2010
(86) PCT No.: PCT/JP2010/067371

§ 371 Date: Feb. 24, 2012

(30) Foreign Application Priority Data
Oct. 5, 2009 (JP) PCT/JP2009/067355

(51) Int. Cl. C23C 16/50; C23C 16/52

(52) U.S. Cl. 427/575; 118/723 AN; 118/708

(57) ABSTRACT

A surface wave plasma CVD apparatus, includes: a waveguide (3) that is connected to a microwave source (2), and in which a plurality of slot antennas (S) are formed thereof; a dielectric plate (4) for conducting microwaves emitted from the plurality of slot antennas (S) into a plasma processing chamber (1) so that a surface wave plasma is produced; an insulating shield member (lb) that is arranged so as to surround a layer formation processing region (R) in which the surface wave plasma is produced; and a gas ejection portion (52) that ejects process material gas into the layer formation processing region (R).

### TECHNICAL FIELD

The present invention relates to a surface wave plasma CVD apparatus, and to a layer formation method that employs this apparatus.

### BACKGROUND ART

A CVD apparatus that utilizes surface wave plasma is per se known from the prior art (refer to Patent Documents #1 and #2). In such a surface wave plasma CVD apparatus, microwaves are introduced through a dielectric window provided to a vacuum chamber, and these microwaves propagate as surface waves along the interface between the plasma and the dielectric window. As a result, a high density plasma is created in the vicinity of the dielectric window. A substrate upon which a layer is to be formed (i.e. that is to be a subject of layer formation) is disposed in a fixed arrangement at a position that opposes the dielectric window.

### CITATION LIST

### Patent Literature

Patent Document #1: Japanese Laid-Open Patent Publication 2005-142448;

Patent Document #2: Japanese Laid-Open Patent Publication 2007-317499.

### SUMMARY OF INVENTION

### Technical Problem

However, the density distribution of the plasma is not necessarily spatially uniform: for example, the density may decrease in the peripheral region next to the wall surface of the chamber. Due to this, it is necessary to set the area of the dielectric plate to be greater than that of the substrate that is to be the subject of layer formation, and it is difficult to control the apparatus to produce a uniform high density plasma over an area of greater than around 2.5 m square like, for example, a liquid crystal glass substrate, and this can also constitute a cause for increase in the cost. Moreover, when a conductor such as the chamber wall is present at the edge of the dielectric plate, electrons in the surface wave plasma are absorbed by this conductor, and as a result the density of the plasma decreases in the neighborhood of the surface of the conductor. Furthermore, there has been the problem that the average density of the plasma also decreases over the entire plasma region due to these electrons being absorbed by the conductor.

### Solution to Problem

(1) According to the 1st aspect of the present invention, a surface wave plasma CVD apparatus comprises: a waveguide that is connected to a microwave source, and in which a plurality of slot antennas are formed on a magnetic field plane thereof; a dielectric plate for conducting microwaves emitted from the plurality of slot antennas into a plasma processing chamber so that a surface wave plasma is produced; an insulating shield member that is arranged so as to surround a layer formation processing region in which the surface wave plasma is produced; and a gas ejection portion that ejects process material gas into the layer formation processing region.

(2) According to the 2nd aspect of the present invention, in a surface wave plasma CVD apparatus according to the 1st aspect, it is preferred that the insulating shield member is made from an insulating material shaped in a plate, and that further comprises a support member that is arranged at an end portion of the layer formation processing region; and wherein the insulating shield member is removably fitted to a side of the support member that faces towards the layer formation processing region.

(3) According to the 3rd aspect of the present invention, in a surface wave plasma CVD apparatus according to the 2nd aspect, it is preferred that the insulating shield member is a thin glass plate.

(4) According to the 4th aspect of the present invention, in a surface wave plasma CVD apparatus according to the 2nd aspect, it is preferred that the insulating shield member is a thin metallic plate whose surface is coated with an insulating layer.

(5) According to the 5th aspect of the present invention, in a surface wave plasma CVD apparatus according to the 2nd aspect, it is preferred that the insulating shield member is a thin insulating plastic plate.

(6) According to the 6th aspect of the present invention, in a surface wave plasma CVD apparatus according to any one of the 1st through 5th aspects, it is preferred that the gas ejection portion is provided to the support member.

(7) According to the 7th aspect of the present invention, a surface wave plasma CVD apparatus according to any one of the 1st through 6th aspects preferably further comprise: a moving device that performs a to and fro motion of a plate-shaped substrate that is to be a subject of layer formation so that the substrate that is to be a subject of layer formation passes through the layer formation processing region, and a control device that controls the to and fro motion by the moving device of the substrate that is to be a subject of layer formation according to layer formation conditions.

(8) According to the 8th aspect of the present invention, in a surface wave plasma CVD apparatus according to any one of the 1st through 5th aspects, it is preferred that the dielectric plate is approximately formed as a rectangle and the insulating shield member is arranged so as to surround the layer formation processing region in a rectangular shape; and further comprises: a plurality of gas ejection portions, provided along at least one long edge of the layer formation processing region, that eject process material gas into the layer formation region; a moving device that performs a to and fro motion of a plate-shaped substrate that is to be a subject of layer formation in a direction orthogonal to the long sides of the layer formation processing region that is surrounded in a rectangular shape by the insulating shield member, so that the substrate that is to be a subject of layer formation passes through the layer formation processing region; and a control device that controls the to and fro motion by the moving device of the substrate that is to be a subject of layer formation, according to conditions for layer formation.

(9) According to the 9th aspect of the present invention, in a surface wave plasma CVD apparatus according to any one of the 1st through 5th aspects, it is preferred that the dielectric plate consists of approximately rectangular first and second dielectric plates arranged side by side so that their long sides neighbor one another, and the insulating shield member is arranged so as to surround the layer formation processing region in a rectangular shape, and further comprising: a dividing wall that is arranged between the first and second rectangular dielectric plates arranged side by side, and that divides the layer formation processing region into first and second divided regions arranged side by side along the direction of the to and fro motion; a plurality of gas ejection portions, provided along respective long edges of the layer formation processing region, that eject process material gas into both the first and the second divided regions; a moving device that performs a to and fro motion of a plate-shaped substrate that is to be a subject of layer formation in a direction orthogonal to the long sides of the layer formation processing region that is surrounded in a rectangular shape by the insulating shield member, so that the substrate that is to be a subject of layer formation passes through the layer formation processing region; and a control device that controls the to and fro motion by the moving device of the substrate that is to be a subject of layer formation, according to conditions for layer formation.

(10) According to the 10th aspect of the present invention, a surface wave plasma CVD apparatus according to the 9th aspect preferably further comprises: a first microwave control means that controls supply of microwaves through the first rectangular dielectric plate; a second microwave control means that controls supply of microwaves through the second rectangular dielectric plate; a first gas control means that controls supply of process material gas to the first divided region; and a second gas control means that controls supply of process material gas to the second divided region.

(11) According to the 11th aspect of the present invention, in a surface wave plasma CVD apparatus according to any one of the 7th through 10th aspects, it is preferred that a first waiting region and a second waiting region are provided within the plasma processing chamber on opposite sides of the layer formation processing region along a moving path of the substrate that is to be a subject of layer formation, and the moving device performs a to and fro motion of the substrate that is to be a subject of layer formation between the first waiting region and the second waiting region.

(12) According to the 12th aspect of the present invention, in a surface wave plasma CVD apparatus according to any one of the 7th through 11th aspects, it is preferred that a back plate that controls temperature of the substrate that is to be a subject of layer formation is disposed in a moving path of the substrate that is a subject of layer formation by the moving device.

(13) According to the 13th aspect of the present invention, a surface wave plasma CVD apparatus according to any one of the 7th through 12th aspects preferably further comprises: a first vacuum vessel within which the moving device and a back plate are disposed, and that has an opening that is positioned to oppose a region in which a to and fro motion of the substrate that is to be a subject of layer formation is performed; and a second vacuum vessel that is connected to the first vacuum vessel via the opening, and within which the dielectric plate and the insulating shield member are disposed.

(14) According to the 14th aspect of the present invention, a surface wave plasma CVD apparatus according to the 1st aspect preferably further comprises a moving device that moves a film-shaped substrate that is to be the subject of layer formation so that it passes through the layer formation processing region, and a cylindrical back plate that controls the temperature of this subject of layer formation.

(15) According to the 15th aspect of the present invention, in a surface wave plasma CVD apparatus according to the 14th aspect, it is preferred that the cylindrical back plate supports the film-shaped substrate in a region that opposes the dielectric plate, and the moving device performs a to and fro motion of the film-shaped substrate over a predetermined section so as to perform layer formation in multiple layers.

(16) According to the 16th aspect of the present invention, a method for forming a layer upon the subject of layer formation with a surface wave plasma CVD apparatus according to any one of the 7th through 15th aspects, wherein the subject of layer formation includes a functional element upon a substrate, and in which a protective layer is formed for protection of the functional element.

(17) According to the 17th aspect of the present invention, a method for forming a layer upon the subject of layer formation with a surface wave plasma CVD apparatus according to any one of the 7th through 15th aspects, wherein thin layers are formed under different layer formation conditions for outward and return paths of the to and fro motion, and formation of a thin layer is performed by the layers formed under different layer formation conditions being laminated together.

### Advantageous Effects of Invention

According to the present invention, it is possible to generate and maintain a plasma of high density over the entire layer formation processing region, and it is possible to manufacture at low cost a thin layer whose properties and thickness are uniform.

### BRIEF DESCRIPTION OF DRAWINGS

FIG. 1 is a figure for explanation of a first embodiment of the present invention, and shows the general structure of a surface wave plasma CVD apparatus;

FIG. 2 is a sectional view of the FIG. 1 apparatus taken in a plane shown by the arrows A-A in FIG. 1;

FIG. 3 is a sectional view of the FIG. 1 apparatus taken in a plane shown by the arrows B-B in FIG. 1;

FIG. 4(a) is a figure showing the way in which an insulating shield is fitted to the inside of a support member of a layer formation processing region, while FIGS. 4(b) and 4(c) show the beneficial effects of this insulating shield;

FIG. 5 is a figure showing a second embodiment;

FIG. 6 is a figure showing an example of a prior art surface wave plasma CVD device, in which reciprocating to and fro movement of the substrate is not performed, and to which an embodiment of the present invention has been applied, and FIG. 6(a) is a plan view thereof, while FIG. 6(b) is an elevation view thereof;

FIG. 7 is a figure showing the relationship between the proportional flow rate of nitrogen within the process gas and the internal stress in a layer of silicon nitride;

FIG. 8 is a figure showing a cross section of a laminated thin layer 100, in which layers of silicon nitride under compressive stress and layers of silicon nitride under tensile stress are laminated alternatingly;

FIG. 9 is a sectional view of an organic EL element that is formed upon a plastic film substrate;

FIG. 10 is a figure showing a variant embodiment;

FIG. 11 is a sectional view of FIG. 10 taken in a plane shown by the arrows B2-B2 in FIG. 10;

FIG. 12 is a figure showing a third embodiment;

FIG. 13 is a figure showing a fourth embodiment;

FIG. 14 is a sectional view of FIG. 13 taken in a plane shown by the arrows B3-B3 in FIGS. 13; and

FIG. 15 is a figure showing a variant of Embodiment #1.

### DESCRIPTION OF EMBODIMENTS

Embodiments for implementation of the present invention will now be explained with reference to the drawings.

### Embodiment #1

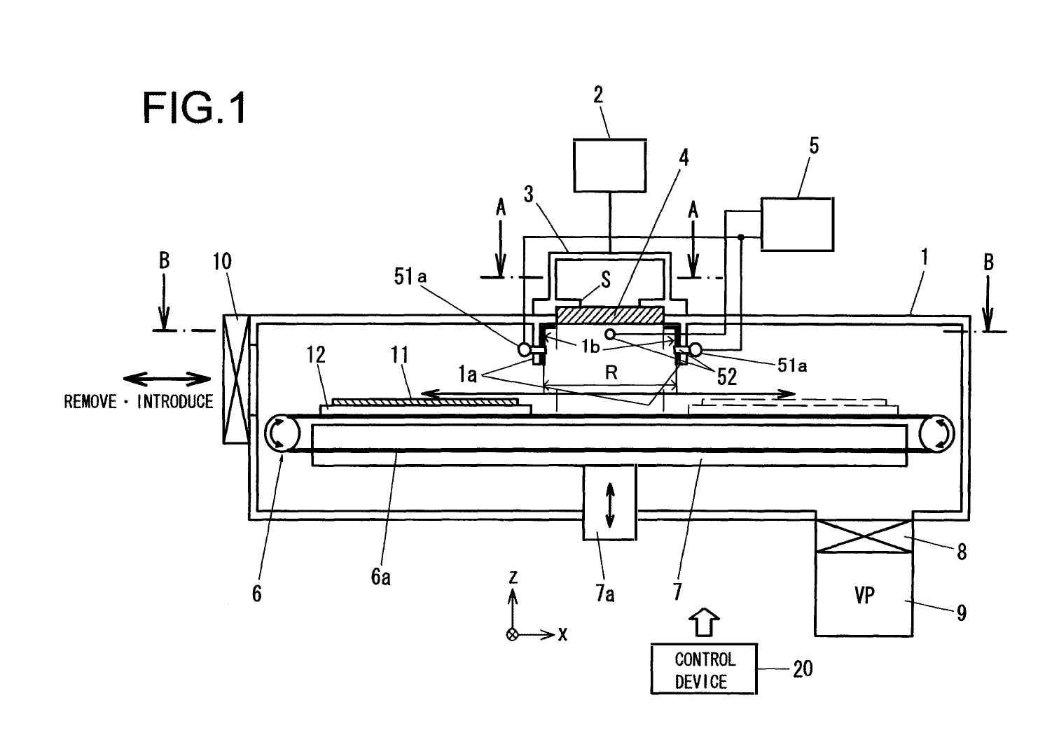

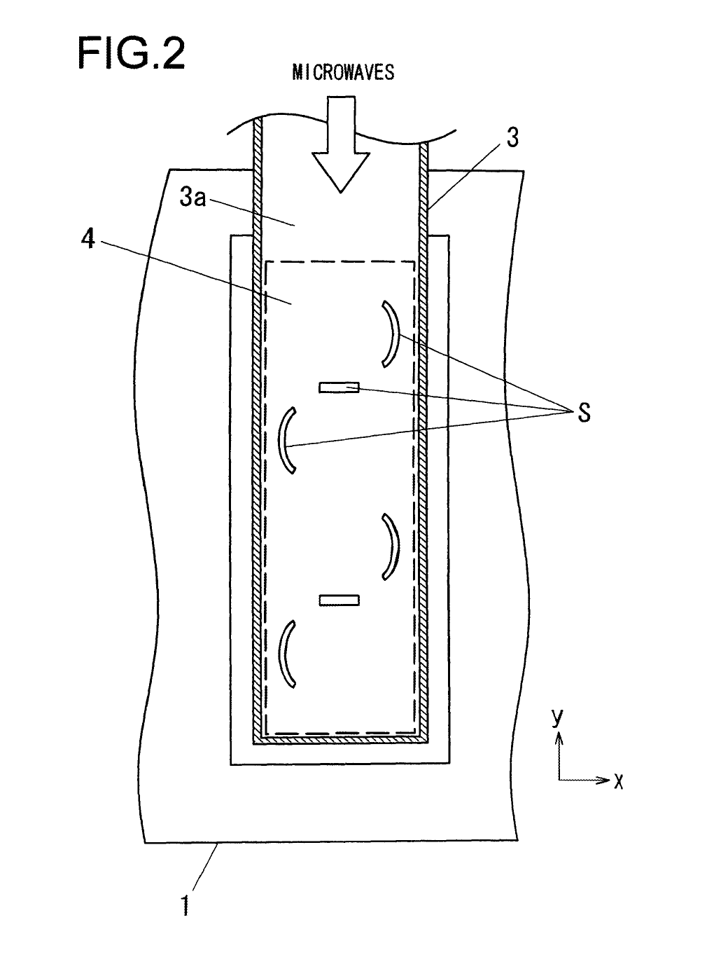

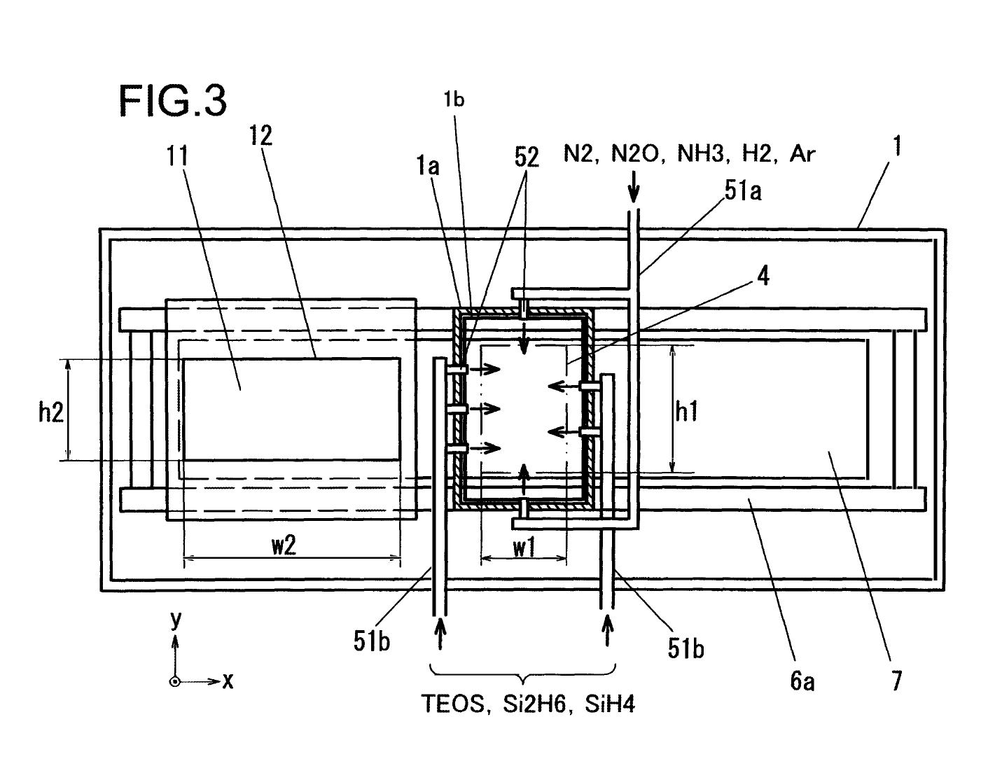

FIGS. 1 through 4 are figures for explanation of the first embodiment of the present invention, and show the general structure of a surface wave plasma CVD apparatus. FIG. 1 is a sectional view of the apparatus as seen from the front, FIG. 2 is a sectional view of the apparatus taken in a plane shown by the arrows A-A in FIG. 1, and FIG. 3 is a sectional view of the apparatus taken in a plane shown by the arrows B-B in FIG. 1. This surface wave plasma CVD apparatus includes a vacuum chamber 1 in which a layer formation process is performed, a microwave output unit 2 that supplies microwaves when generating a surface wave plasma, a waveguide 3, a dielectric plate 4, a gas supply device 5, a substrate moving device 6, and a control device 20.

The dielectric plate 4 is shaped as a flat plate made from quartz or the like, and is provided above the upper portion of the vacuum chamber 1. The region denoted by the reference symbol R that opposes the dielectric plate 4 is a layer formation processing region in which formation of a layer upon the substrate 11 is performed. This layer formation processing region R is a space surrounded by an insulating shield member lb that is provided so as to surround the dielectric plate 4. This insulating shield member lb may, for example, be a plate shaped insulating member that is removably attached by claw shaped metal lugs. The waveguide 3 is mounted above the dielectric plate 4, and microwaves from the microwave output unit 2 (that may, for example, be microwaves of frequency 2.45 GHz) are inputted to the waveguide 3. The microwave output unit 2 includes a microwave power supply, a microwave oscillator, an isolator, a directional coupler, and an impedance matching device.

As shown by the broken line in FIG. 2, the dielectric plate 4 is formed in the shape of a long rectangle extending along the Y direction. As shown in FIG. 1, the upper surface of the dielectric plate 4 contacts a bottom plate 3a of the waveguide 3. A number of slot antennas S are formed in the portion of the bottom plate 3a that contacts the dielectric plate 4, these being apertures for emission of microwaves. The microwaves fed in from the microwave output unit 2 form standing waves within the waveguide 3. It should be understood that, as described in Patent Document #2, this plurality of slot antennas S is formed on the magnetic field plane of the standing waves of the microwaves within the waveguide 3.

As shown in FIG. 3, gas for plasma generation and process material gas for layer formation that are supplied from the gas supply device 5 are introduced into the vacuum chamber 1 via gas supply conduits 51a and 51b. A support member 1a is provided within the vacuum chamber 1 around the periphery of the dielectric plate 4, and the gas supply conduits 51a and 51b are fixed to this support member 1a. Plasma is generated directly underneath the dielectric plate 4. The gases from the gas supply device 5 are ejected into the plasma region from gas ejection portions 52. Mass flow controllers for each type of gas are provided to the gas supply device 5, and the turning on and off of each gas and control of its flow rate can be performed by these mass flow controllers under the control of the control device 20.

A Gas acting as a raw material of a reactive active species, such as N₂, N₂O, NH₃, H₂ or the like, and an inert gas, such as Ar or the like, are supplied from the gas supply conduit 51a that is provided in a position close to the dielectric plate 4. Moreover, a gas such as TEOS, Si₂H₆, SiH₄ or the like is supplied as a process material gas from the gas supply conduit 51b that is provided in a position whose distance from the dielectric plate 4 is greater than that of the gas supply conduit 51a. The distances of the gas supply conduits 51a and 51b from the dielectric plate 4 are different, and the distance of the gas supply conduit 51a from the dielectric plate 4 is the smaller. In this embodiment, the gas supply conduits 51a and 51b are arranged on the outside of the support member 1a. Since the plasma is generated in the region that is surrounded by the insulating shield member lb, accordingly the gas supply conduits 51a and 51b are not exposed to the plasma, so that the problems do not arise, as in the prior art, of a layer formation on the gas supply conduits due to the gas supply conduits being arranged in the plasma region, or of particles produced through detachment of such a layer.

As shown in FIG. 1, the interior of the vacuum chamber 1 is evacuated by a vacuum pumping device 9 that is connected thereto via a conductance valve 8. A turbomolecular pump is used in the vacuum pumping device 9. A substrate 11 that is to be a subject for layer formation is mounted upon a tray 12, and this tray 12 is conveyed via a gate valve 10 into the interior of the vacuum chamber 1 upon a conveyor belt 6a of the substrate moving device 6 that is provided within the vacuum chamber 1. Moreover, when the formation of a layer upon the substrate 11 has been completed, it is removed from the vacuum chamber 1 via the gate valve 10, while still being in the state of being mounted upon the tray 12. It should be understood that it would also be acceptable to mount the substrate 11 directly upon the conveyor belt 6a, without employing any tray 12.

During layer formation, the substrate moving device 6 moves the tray 12 upon the conveyor belt 6a to and fro in the left and right directions in FIG. 1 (i.e. along the X direction, this being the lengthwise direction). As shown in FIG. 3, the dielectric plate 4 is shaped as rectangular, with the direction of extension of its short sides being parallel to the moving direction of the substrate 11 (i.e. the X direction, this being the lengthwise direction). The longitudinal dimension of the dielectric plate 4 (i.e. its dimension in the Y direction) h1 is set to be greater than the dimension h2 of the substrate 1 in the Y direction. In other words, this dimension h1 is set so that h1>h2. On the other hand, the lengthwise dimension w2 of the substrate 11 has no relation to the lengthwise dimension w1 of the dielectric plate 4, but w2 is directly proportional to the moving distance.

A back plate 7 is provided for adjusting the temperature of the substrate 11, and the temperature thereof can be adjusted by provision of a heater or a cooling device, although this feature is not shown in the figures. For example, the desired CVD processing conditions may be obtained by applying heat to the tray 12 and the substrate 11, thus controlling their temperatures. Moreover, elevation of the temperature of the substrate 11 and the tray 12 may be controlled by circulating refrigerant to a cooling device. A drive device 7a is provided to the back plate 7 for driving the position of the back plate 7 in the vertical direction (i.e. in the Z direction), and it is possible to perform adjustment of the gap between the back plate 7 and the tray 12 by driving this drive device 7a. The control device 20 controls the operation of the microwave output unit 2, the gas supply device 5, the substrate moving device 6, the drive device 7a, the conductance valve 8, the vacuum pumping device 9, and the gate valve 10.

### <Explanation of the Operation>

Next, the layer formation operation will be explained in terms of an example in which a layer of silicon nitride is formed. In this case, Ar gas and NH₃ or N₂ gas are supplied from the gas supply conduit 51a, and SiH₄ gas is supplied from the gas supply conduit 51b. When the microwaves that are emitted from the slot antennas S of the waveguide 3 pass through the dielectric plate 4 into the vacuum chamber 1, the gas molecules are ionized and/or dissociated by these microwaves, so that a plasma is generated. And if the density of electrons within the plasma in the vicinity of the surface at which the microwaves are incident is greater than the cutoff density of the microwaves, then the microwaves no longer penetrate into the plasma, but are propagated as surface waves along the interface between the plasma and the dielectric plate 4. As a result, a surface wave plasma comes to be formed close to the dielectric plate 4, with energy being supplied thereto via these surface waves.

With a surface wave plasma, the electronic temperature is high in the neighborhood of the dielectric plate 4, while the electronic temperature becomes lower along with increasing distance from the dielectric plate 4. Since a high energy region and a low energy region are set up in this way according to distance from the dielectric plate 4, accordingly production of radicals is performed in the high energy region, and, due to the SiH₄ that is the material gas being introduced into the low energy region, the radicals can be produced at high efficiency, and a high rate layer formation at low temperature and with little damage at high speed becomes possible.

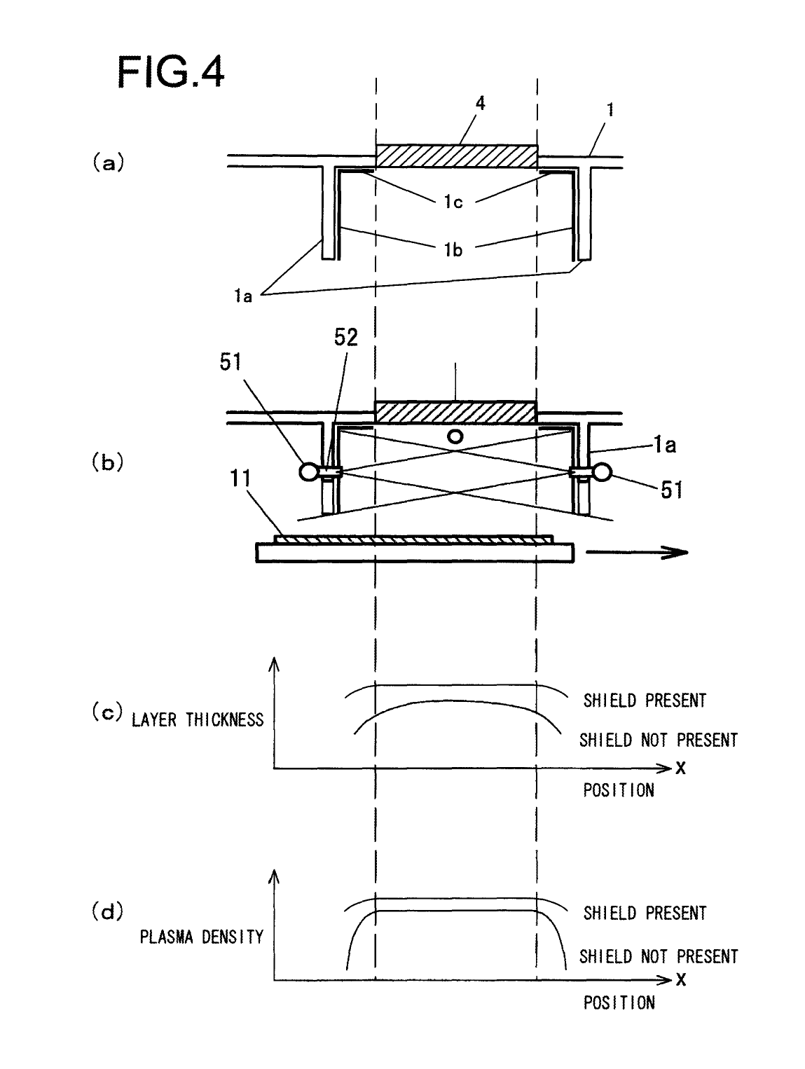

FIG. 4 shows the beneficial effect provided by the insulating shield member 1b that, according to the present invention, is fitted upon the support member 1a on the side of the layer formation processing region. FIG. 4(a) shows the way in which the insulating shield member 1b is fitted to the the support member 1a on its side facing the layer formation processing region (on the side of the dielectric plate 4). Normally, the support member 1a is made from an electrically conductive metal. While the material used for the insulating shield member 1b is not particularly limited provided that it is made from an insulating material, it is desirable to make it from a thin glass plate or from a thin insulating plastic plate, so that no undesired emissions are evolved from it in the vacuum state. If, as shown in FIG. 4(a), the support member 1a is provided so as to be somewhat separated from the edge portion of the dielectric plate 4, then it is desirable for an insulating shield member 1c also to be arranged on the chamber side surface between the support member 1a and the dielectric plate 4 in the vacuum chamber 1. It should be understood that in FIG. 4(a), in order to make the drawing easier to understand, the gas supply conduits 51a and 51b and the gas ejection portions 52 are omitted.

FIG. 4(b) is a figure schematically showing the ejection of gas from the gas ejection portions 52.

If, for example, no insulating shield member 1b is used, and the layer formation processing region is simply surrounded by the support member 1a that is made from an electrically conductive material, then, in the vicinity of the support member 1, the electrons in the plasma will be rapidly absorbed and the electronic density will decrease in this region, and, according to this, the density of the plasma also will decrease there. This decrease of the density of the plasma there will influence the entire plasma, so that the density of the entire plasma mass also will decrease (see FIG. 4(d). By contrast, if the insulating shield 1b is provided to the support member 1a, then the electrons in the plasma are not absorbed even close to the insulating shield member 1b, and as a result decrease of the density of the plasma there is suppressed, so that decrease of the density of the entire plasma is also suppressed.

Not only does the presence of the insulating shield member 1b suppress decrease in the density of the plasma in the manner described above, but also, by using an insulating member that can be removed, the additional beneficial effect is obtained that maintenance of the apparatus can be performed easily.

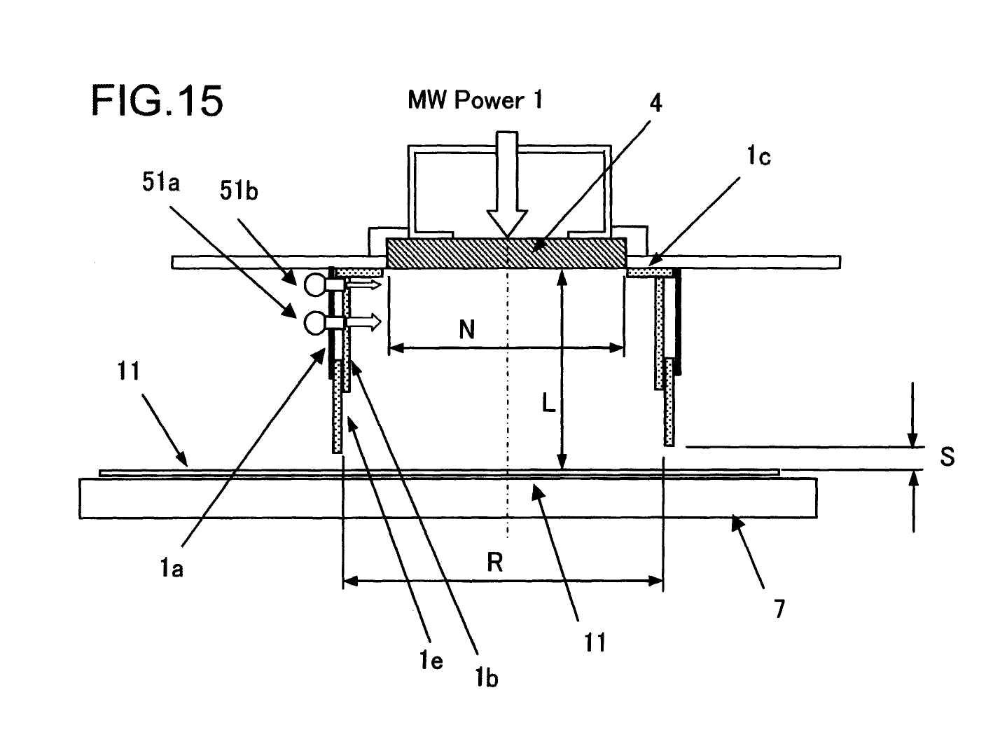

It should be understood that, as shown in FIG. 15, it would also be acceptable additionally to provide a second insulating shield 1e. With the surface wave plasma CVD apparatus of this embodiment, if the distance between the dielectric plate 4 and the substrate 11 is termed L and the clearance between the insulating shield 1e and the substrate 11 is termed S, then it is desirable for S to be 10% or less of L.

If the clearance S shown in FIG. 15 is large, then the range of layer formation becomes greater due to the influence of plasma and radicals that leak out. In this case, sometimes it may happen that the quality of the thin layer that is formed in the area where the density of the plasma is lower is different from the quality of the layer that is formed in the layer processing region range denoted by the reference symbol R in FIG. 15. Due to this, the provision of the insulating shield 1e and arranging it so that the clearance S becomes as small as possible ensure that the quality of the layer produced will be uniform.

Furthermore, by making the clearance S small by the provision of the insulating shield 1e and thus suppressing leakage of plasma and radicals, it becomes possible to make the apparatus more compact by making it possible for the waiting positions of the substrate and the layer formation position thereof to be brought closer together. In this embodiment, if L=200 mm, the clearance S is set to equal 10 mm to 15 mm.

It should be understood that, when adjusting the drive device 7a that drives the position of the substrate 11 along the Z direction, component exchange is performed by adjusting the insulating shield 1e according to the dimensions L and S. Alternatively, it would also be acceptable to make the insulating shield 1e shiftable in the Z direction, so that it can be arranged to adjust the position of the insulating shield 1e in the Z direction together with driving the drive device 7a.

In pre-processing, the substrate 11 is heated up in advance to a predetermined temperature by the application of heat, and is conveyed upon the conveyor belt 6a in the state of being mounted upon the tray 12. Then the substrate moving device 6 starts driving the tray 12 to and fro. Due to this reciprocating moving operation, the substrate 11 is moved to and fro between a position (a first waiting position shown by the solid lines in FIG. 1) beyond the left side of the plasma region within the vacuum chamber 1, and a position (a second waiting position shown by the broken lines in FIG. 1) beyond the right side of the plasma region. In either of these left and right waiting positions, the substrate 11 is in a state of having completely passed through the area where the substrate opposes the plasma region that is surrounded by the insulating shield member 1b.

While the substrate 11 is passing right under the region surrounded by the insulating shield member 1b in which the surface wave plasma is being generated, a thin layer of silicon nitride is formed upon the substrate 11. The thickness of the silicon nitride layer that is formed at this time depends upon the speed with which the substrate 11 is moved. The moving speed may, for example, be set to around 10 mm/sec to 300 mm/sec. The substrate moving device 6 performs a deceleration operation and stops the movement of the substrate 11 after the trailing edge portion of the substrate 11 in its current direction of progression passes the layer formation region underneath the support member 1a. Then the moving direction of the substrate 11 is changed over, and it is accelerated until it reaches the moving speed described above before its leading edge portion in its new direction of progression reaches the layer formation region underneath the support member 1a. In other words, the substrate 11 passes through the layer formation region underneath the support member 1a while being moved at a constant speed. Due to this, each time the substrate 11 passes directly underneath the support member 1a once, a thin layer of silicon nitride is formed thereupon, having a uniform thickness according to the speed of this moving. And finally, a number of layers of silicon nitride come to be formed upon the substrate 11, equal in number to the total number of times the substrate 11 has passed to and fro.

In some cases, such as for provision of a barrier against water vapor or some other gas, there is a demand for formation of a layer that is made up from a number of very thin layers whose morphologies are different even though their thicknesses are the same, so that it is necessary to combine a number of such thin layers by forming them during to and fro reciprocating motion. While in some cases, during a vacuum layer formation process such as spattering or CVD, it may happen that the state of the foundation is hereditarily inherited in the formation of the thin layers, on the other hand, in the case of layer formation while moving to and fro, this hereditary inheritance of the state of the foundation in the states of the thin layers that are formed is mitigated, as compared to formation of layers upon a stationary substrate. It should be understood that it is simple and easy to perform further control for laminating together very thin layers of different types by actively changing, for example, the supply ratios of silane gas and ammonia gas, between on the outward path and on the return.

It should be understood that, with a capacity coupled plasma CVD apparatus or an induction coupled plasma CVD apparatus, it is essential to have a stable electrical coupling between the cathode and the anode in order to obtain stable electrical discharge. Due to this, if the substrate (that is on the anode side) moves during discharge, then the balance of electrical potential between the electrodes changes, and stable electrical discharge is not obtained, so that the problem arises that a uniform layer quality, layer thickness, and layer formation speed cannot be obtained. Moreover it is known that anomalous electrical discharge such as arcing or the like is induced when the substrate moves, so that the problem also arises that the yield rate reduces very badly due to deterioration of the layer quality and due to the creation of particles. On the other hand, with the surface wave plasma CVD method as used in this embodiment, since there is no electrode discharge, there is no danger of problems like those above described occurring even when substrate moving or the like is performed.

Moreover, a surface wave plasma is a plasma of high density and low electronic temperature, so that the damage to the semiconductor device caused by plasma is extremely low. Due to this, even on a semiconductor device, such as an thin organic layer device, that has low resistance to temperature or plasma it is possible to form a thin layer of inorganic insulation thereupon as a protective layer.

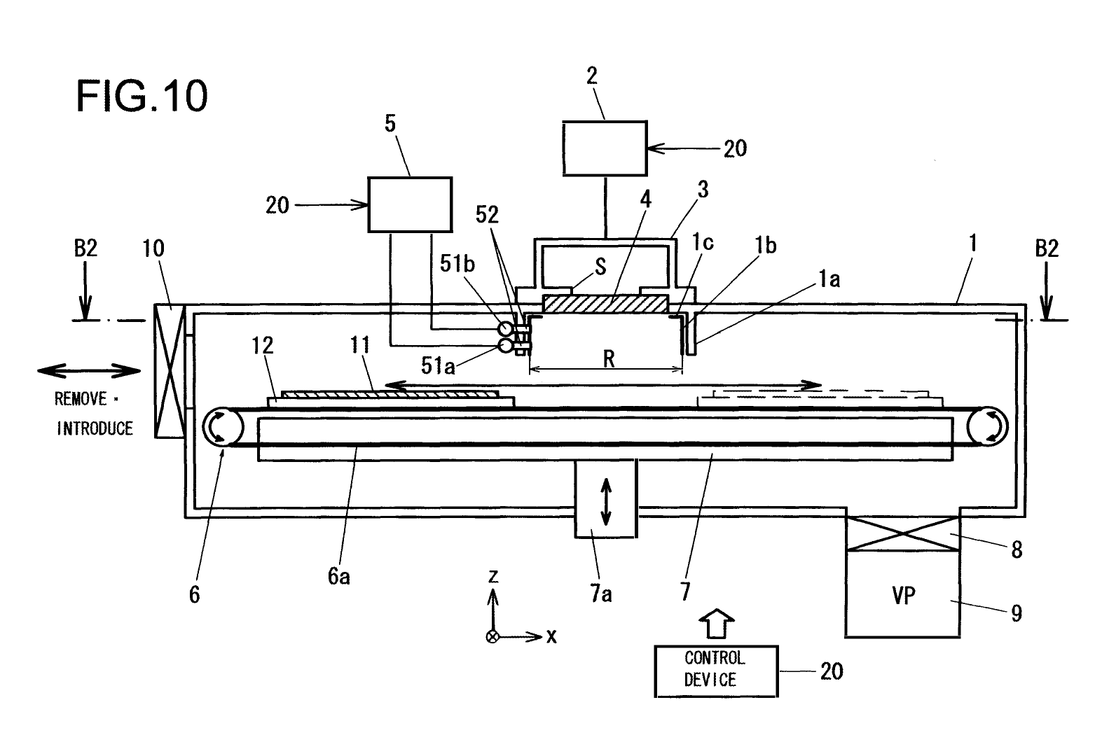

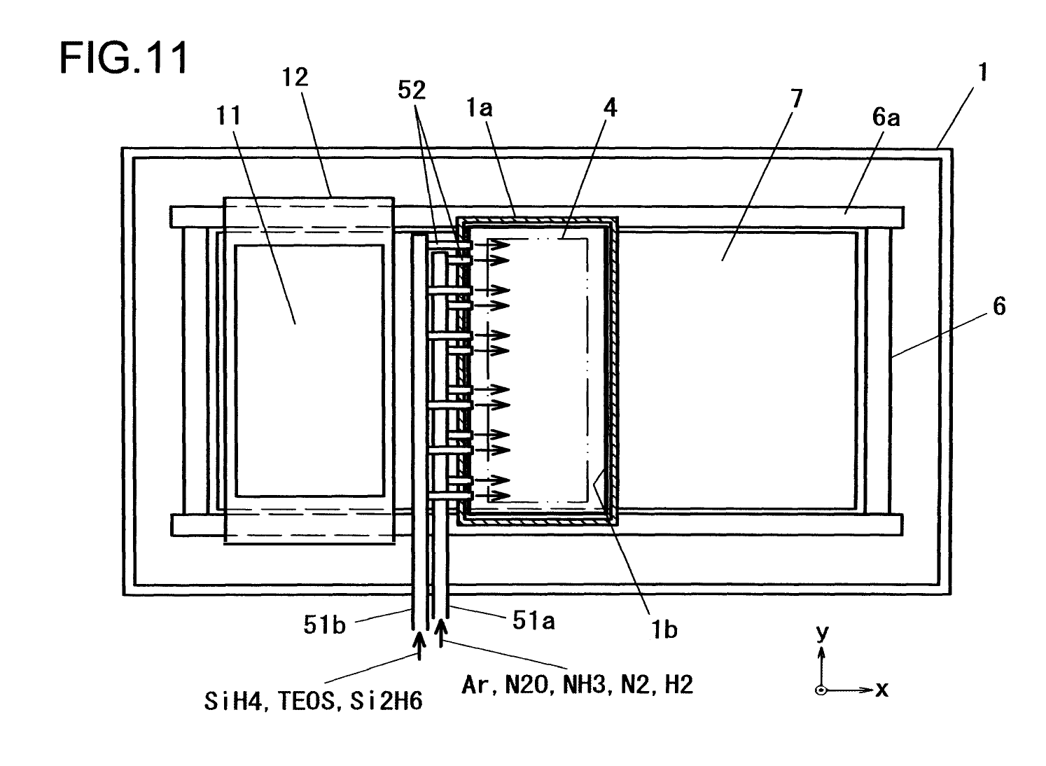

It should be understood that while, with the apparatus shown in FIGS. 1 and 3, the gas ejection portions 52 are arranged so as to face one another with the dielectric plate 4 between them, it would also be acceptable to install them all upon one edge of the rectangular support member 1a. The apparatus shown in FIGS. 10 and 11 is an example of this type, and, in this apparatus, the plurality of gas ejection portions 52 are arranged along one of the long edges of the dielectric plate 4, this being formed as a rectangle. FIG. 10 is an elevation view similar to FIG. 1. And FIG. 11 is a sectional view similar to FIG. 3, being a cross sectional view taken in a plane shown by the arrows B2-B2 in FIG. 10. It should be understood that to structural elements of this apparatus of FIGS. 10 and 11 that correspond to similar structural elements of the apparatus shown in FIGS. 1 and 3, the same reference symbols are appended, and that the following explanation will concentrate upon the portions that are different from those of the apparatus shown in FIGS. 1 and 3.

In the case of the apparatus shown in FIGS. 10 and 11, the gas ejection portions 52 of the gas supply conduits 51a and 51b are all arranged along one long side of the support member 1a (the long side thereof on the left side as seen in FIG. 11). The plurality of gas ejection portions 52 provided to the gas supply conduits 51a and 51b are arranged along this long side. In the example shown in FIGS. 10 and 11, the tray 12 is formed as a rectangle that is longer in the direction orthogonal to its direction of moving, and, in the case of a rectangular substrate 11, this is mounted upon the tray 12 so that its longitudinal direction is orthogonal to the direction in which it is moved.

Due to this, if a substrate is to be processed that is wider as compared to one processed with the apparatus shown in FIGS. 1 and 3, then the dimension of the dielectric plate 4 in the Y direction becomes longer. In the case of this type of structure, if as with the apparatus shown in FIG. 3 the gas supply conduit 51a were to be provided at the short side portions of the support member 1a (i.e. at the portions at its top and bottom as seen in FIG. 11), then the distance from the gas ejection portions 52 of the gas supply conduit 51a to the center of the substrate would become long and the beneficial effect of the gas would be reduced at the center of the substrate and further along it. As a result, the uniformity of the layer that was formed would become lost with regard to the Y direction.

On the other hand, with the apparatus shown in FIGS. 10 and 11, all of the gas ejection portions 52 are provided along only one long side portion of the support member 1a. Since the plurality of gas ejection portions 52 are all arranged along one long side, accordingly it is possible to supply the gas more uniformly with regard to both the X direction and the Y direction. In this case as well, the positions of gas ejection and the number of the gas ejection portions 52 are optimized so that it is possible to obtain uniform layer formation. It should be understood that, although in this case the gas ejection portions 52 are only provided along one of the pair of long side portions, it is still possible to obtain a layer whose condition is uniform (i.e. whose thickness and composition are uniform) by performing layer formation while moving the substrate 11 in the X direction, since the width of the layer formation processing region R in the X direction is narrow.

Moreover, when this apparatus is compared with the apparatus shown in FIG. 1, since the substrate 11 is moved in the direction in which its width is narrow, accordingly it is possible to make the moving distance when moving the substrate 11 to and fro shorter.

Due to this, even though the speed for moving the substrate is the same, it may be expected that the time period for moving it to and fro, in other words the time required for layer formation, will be shortened. It should be understood that, in relation to the insulating shield members 1b and 1c, the same beneficial effects during operation are obtained as in the case of the apparatus shown in FIGS. 1 and 3.

### Embodiment #2

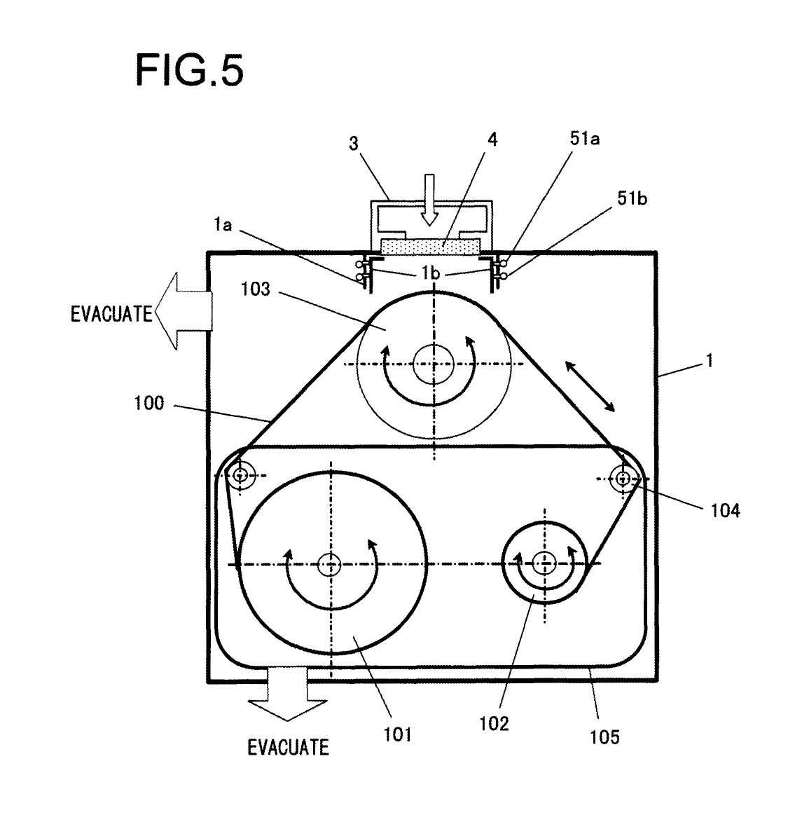

While, in Embodiment #1 described above, the subject upon which a layer was formed was a planar substrate such as a glass substrate, in this second embodiment formation of a thin layer is performed upon a substrate that is made from a flexible film like the one shown in FIG. 5 (hereinafter termed a film substrate). A dielectric plate 4 and a waveguide 3 are provided at the upper portion of a vacuum chamber 1. A support member 1a and a rectangular shaped insulating shield member 1b are provided within the vacuum chamber 1 so as to surround the dielectric plate 4. And gas supply conduits 51a and 51b are connected to the support member 1a.

A film substrate 100 is wound upon a feed reel 101 on the left side as seen in the figure, and, after formation of a layer thereupon, the film substrate 100 is wound up upon a reel 102 on the right side as seen in the figure. The reels 101 and 102 also function as moving devices for moving the film substrate 100 to and fro. A cylindrical back plate 103 is provided in a position opposing the dielectric plate 4, and, between the reels 101 and 102, the film substrate 100 is passed over the upper surface of this back plate 103 and is put thereagainst. The back plate 103 rotates together with the moving of the film substrate 100. And 104 denotes an idler for adjusting the tension of the film substrate 100.

The reels 101 and 102 and the idler 104 are housed within a casing 105. Apart from being formed with slits for the film substrate 100 to enter and exit, this casing 105 is isolated from the vacuum chamber 1. The internal space within the casing 105 is vacuum pumped separately from the vacuum chamber 1, and the pressure within the casing 105 is set to be slightly lower than the pressure within the vacuum chamber 1. In other words, deposition of particles inside the casing 105 onto the film substrate 100 is prevented by setting the pressure within the casing 105 to be negative with respect to the pressure in the vacuum chamber 1.

In the case of the apparatus shown in FIG. 5, it would be possible to arrange to form a thin layer upon the surface of the film substrate 100 while moving the film substrate 100 only in one direction; or, alternatively, it would also be acceptable to arrange to perform layer formation several times in order to form a multi-layered laminate by moving a predetermined section of the film substrate 100 to and fro, whereby the film substrate 100 is processed with index. By performing such reciprocating to and fro movement, similar beneficial effects are obtained as in the case of Embodiment #1 described above.

As in the first embodiment described above, a surface wave plasma CVD device that performs layer formation by moving the film substrate 11 to and fro, the second embodiment has the following beneficial operational effects. It should be understood that, in this second embodiment, it is only the subject of layer formation and the form of the device for moving it that are different from the case of the first embodiment, and accordingly, while the same beneficial operational effects are obtained with this surface wave plasma CVD device of Embodiment #2 as in the case of that of Embodiment #1, they will be explained below in terms of the description of Embodiment #1.

(1) Since layer formation is performed while moving the substrate 11 to and fro so that it repeatedly passes through and underneath the plasma region, in other words through and underneath the layer formation processing region that opposes the dielectric plate 4, accordingly, as shown in FIG. 3, the dimension W2 of the dielectric plate 4 along the direction in which the substrate 11 is moved (i.e. along the X direction) can be set to be smaller than the dimension W1 of the substrate 11 in its moving direction, so that it becomes possible to make the plasma generation portion of the apparatus more compact, and thus reduction of the cost may be anticipated. In particular, it is possible to perform layer formation upon a larger substrate 11 by making the longitudinal direction of the substrate 11 agree with the direction in which it is moved.

(2) Moreover, since the formation of the layers is performed while moving the substrate 11 with respect to the dielectric plate 4, accordingly, even if a difference in the layer formation speed is present due to the position in the X direction, still this non-uniformity over the layer formation processing region is averaged out over the substrate 11, and as a result it is possible to form a thin layer of uniform thickness.

(3) Furthermore, in particular with the present invention, due to the beneficial effect of the insulating shield member 1b that is provided to the support member 1a, it is possible to implement increase of the density of the plasma and enhancement of the uniformity of the plasma density in the layer formation processing region, and due to this the uniformity of the layer formation and the speed of the layer formation are further improved.

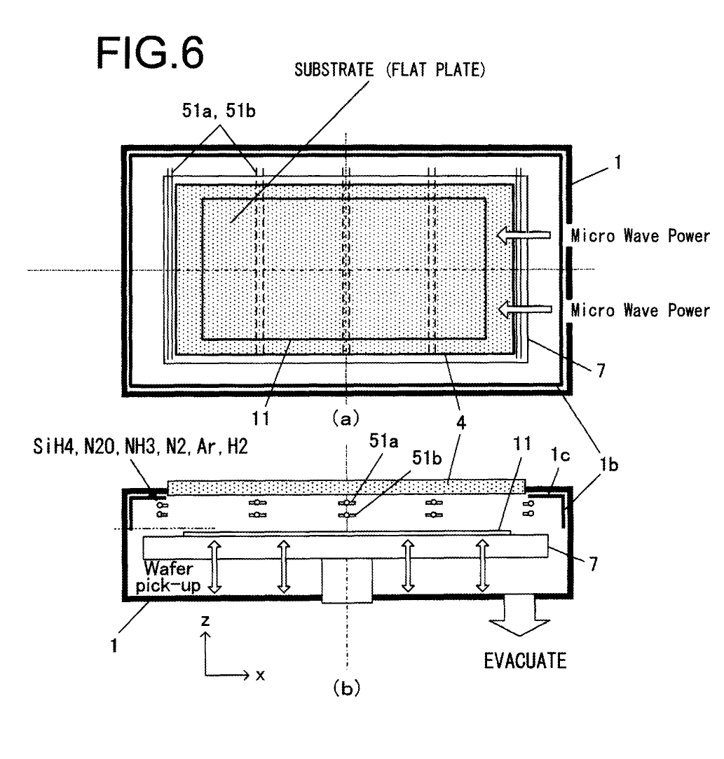

FIG. 6 is a figure showing an example of a prior art surface wave plasma CVD device in which reciprocating to and fro movement of the substrate is not performed, and to which the insulating shield members 1b and 1c of the present invention have been fitted. The substrate 11 is mounted upon a back plate 7, and layer formation is performed in this state. If no such insulating shield members are provided, then the density of the plasma decreases abruptly in the vicinity of the chamber wall. In the prior art, in consideration of this decrease of the density of the plasma near the edge of the chamber, the dielectric plate 4, i.e. the plasma generation portion, is set to an area that is sufficiently greater in size than the substrate. The substrate shown in FIG. 6 is a substrate of a size that is appropriate when no insulating shield members are employed. However, if the insulating shield members of the present invention are employed, then it becomes possible to process a substrate that is larger than the substrate shown in FIG. 6, and it is possible more effectively to utilize the dielectric plate 4, that is high in price.

Moreover, in the prior art, if layer formation was to be performed upon a large substrate, then it was necessary to provide a dielectric plate 4 of a size corresponding thereto, and, if the area of the dielectric plate 4 was large, then it was necessary to increase the number of waveguides that were installed. While the waveguides are not shown in FIG. 6, the direction in which the microwaves are introduced is shown by the arrow signs. Thus, with a prior art apparatus in which formation of a layer was performed upon a fixed substrate in this manner, it was not possible to avoid increase in cost when the area of the substrate increased, since the dielectric plate 4 of the plasma generation portion also increased in size in accordance therewith, and the number of waveguides and the number of microwave power systems also were unavoidably increased.

Furthermore, in order to perform formation of a uniform layer over the entire substrate, it was necessary to supply the material gas uniformly over the entire plasma region, but the difficulty of introducing the gas uniformly increased when the size of the dielectric plate increased. Due to problems with contamination as described above, it is not desirable to dispose the gas supply conduits for introduction of the gas within the space in which the plasma is generated. However if, as shown in FIG. 6, the range for layer formation in the X direction is large, then it becomes inevitable that the gas supply conduits must be disposed within the plasma generation region, in order to make the distribution of the supplied gas uniform.

(4) On the other hand, with the apparatus of Embodiment #1 according to the present invention, since it is possible to make the dimension of the dielectric plate in the direction in which the substrate is moved be smaller than in the prior art, accordingly, as shown in FIG. 3, by arranging the gas supply conduits outside the insulating shield member 1b and by supplying the gas from the periphery thereof, it is possible to supply the gas uniformly even though the gas supply conduits are not disposed within the plasma. As a result, the beneficial operational effect is obtained that it is possible to avoid the problem of contamination caused by the gas supply conduits being arranged within the plasma.

(5) Furthermore, in addition to the beneficial operational effects described above, since it is arranged to perform the formation of successive layers while moving the substrate 11 reciprocatingly to and fro with respect to the layer formation processing region that opposes the dielectric plate 4, accordingly it becomes simple and easy to perform formation of thin layers whose qualities such as refractive index and internal stress and so on are different, by varying the process conditions (such as the ratio of the gas flow rates and the pressure and so on) when moving the substrate 11 in one direction (i.e. in the rightwards direction in FIG. 1), and the process conditions when moving the substrate 11 back in the other direction (i.e. in the leftwards direction in that figure).

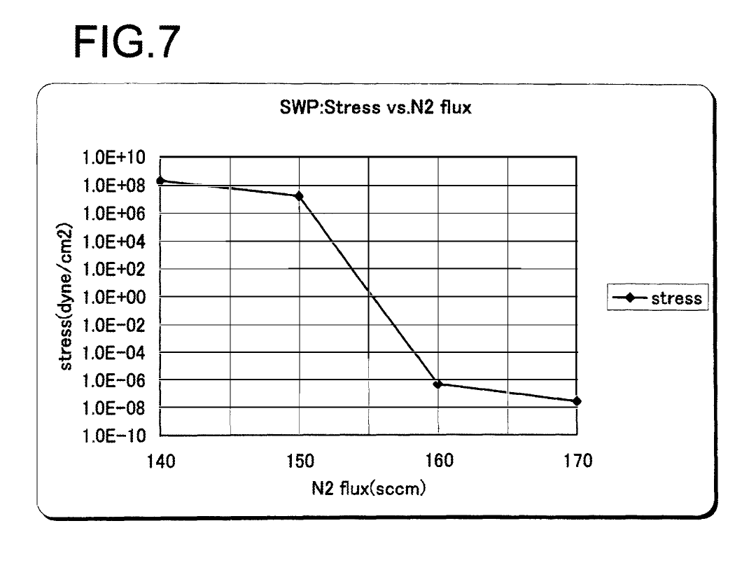

FIG. 7 is a figure showing the relationship between the proportional flow rate of nitrogen within the process gas and the internal stress in the layer of silicon nitride that is formed, and shows the change of the internal stress when the flow rate of the nitrogen gas is changed in the state with the flow rate of SiH₄ being kept constant. If the flow rate of nitrogen is 150 sccm or less, then the internal stress becomes positive, and this corresponds to a tensile stress. Conversely, if the flow rate of nitrogen is 160 sccm or greater, then the internal stress becomes negative, and this corresponds to a compressive stress.

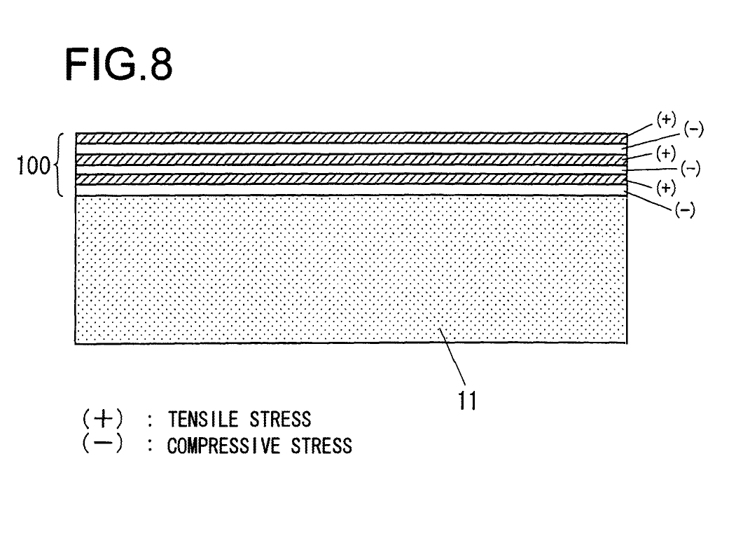

By utilizing this sort of characteristic, it is possible to set the nitrogen flow rate during the layer formation process in the one direction to 160 sccm or greater so as to form a layer of silicon nitride (having thickness of several nanometers) which has internal stress in the compressive direction, and to set the nitrogen flow rate during the layer formation process in the other direction to 150 sccm or less so as to form a layer of silicon nitride (also having thickness of several nanometers) which has internal stress in the tensile direction; and then, as shown in FIG. 8, a laminated thin layer 100 is formed in which layers of silicon nitride under compressive stress and layers of silicon nitride under tensile stress are laminated together alternatingly. As a result, it becomes possible to form a thin layer whose internal stress is low.

Of course, even with a prior art type surface wave plasma CVD device, it is possible to form multiple alternate layers in which layers having tensile stress and layers having compressive stress are independently processed alternately. However, with the surface wave plasma CVD device of this embodiment, since the process of layer formation is performed by moving the substrate 11 to and fro with respect to the layer formation processing region that opposes the dielectric plate 4, accordingly it is possible to form a succession of extremely thin layers in a simple and easy manner by increasing the speed of moving. As a result it becomes possible to make the thickness of a single layer extremely thin, and moreover, by forming a number of layers successively, it becomes possible to invert the stress at the interface between each successive layer and the next so as to keep the overall stress low, and accordingly it becomes possible to obtain a thin layer that is well stabilized.

For example, it is possible to employ this type of laminated layer as a protective layer for a functional element of an organic EL element or for an element for a magnetic head or the like. In the case of an organic EL element, while in some cases a layer of silicon nitride is formed as a protective layer for keeping moisture or oxygen away from an organic EL layer, since such an organic EL layer is not a mechanically solid layer, there is the problem that, if the internal stress in the layer of silicon nitride is high, then the layer of silicon nitride may become detached. However, it is possible to prevent such detachment of the layer of silicon nitride by using, for this type of protective layer, the above laminated thin layer 100 as shown in FIG. 8 whose internal stress is extremely low.

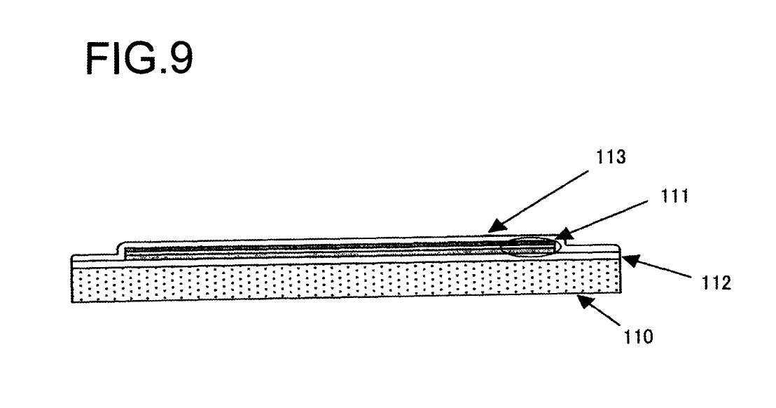

FIG. 9 is a figure showing an example of a case in which an organic EL element 111 is formed upon a plastic film substrate 110. An inorganic protective layer 112 is formed upon the plastic film substrate 110, and then the organic EL element 111 is formed over that. Furthermore, an inorganic protective layer 113 is formed so as to cover over this organic EL element 111. Layers of silicon nitride as described above are used for these laminated thin layers, as the inorganic protective layers 112 and 113.

With the thin laminated layer 100 described above, a protective layer whose internal stress is low is formed by laminating together numerous layers whose conditions of formation (i.e. nitrogen flow rate) are different. In a similar manner, by employing a multi layered construction in which layers whose formation conditions are slightly different are alternatingly superimposed, it is possible to form a protective layer whose protective function with respect to permeation of moisture or oxygen is high as compared to a single layered protective layer of the same thickness.

While, in the example described above, an example was described of a multiple layered structure in which layers of silicon nitride of different construction were alternatingly laminated together, it would also be possible to apply the present invention to a multiple layered structure in which thin layers of different components are alternatingly laminated together, such as multiple layers of silicon oxynitride and layers of silicon nitride. At the timings for the formation of the layers of silicon nitride, NH₃ and N₂ gases are supplied from the gas supply conduit 51a in a similar manner to that described above, and SiH₄ gas is supplied from the gas supply conduit 51b. On the other hand, at the timings for the formation of the layers of silicon oxynitride, SiH₄ gas and N₂O gas are supplied, or TEOS gas and oxygen gas. And changing over of the gas that is supplied is performed, each time the substrate 11 passes through the region underneath the dielectric plate 4.

### Embodiment #3

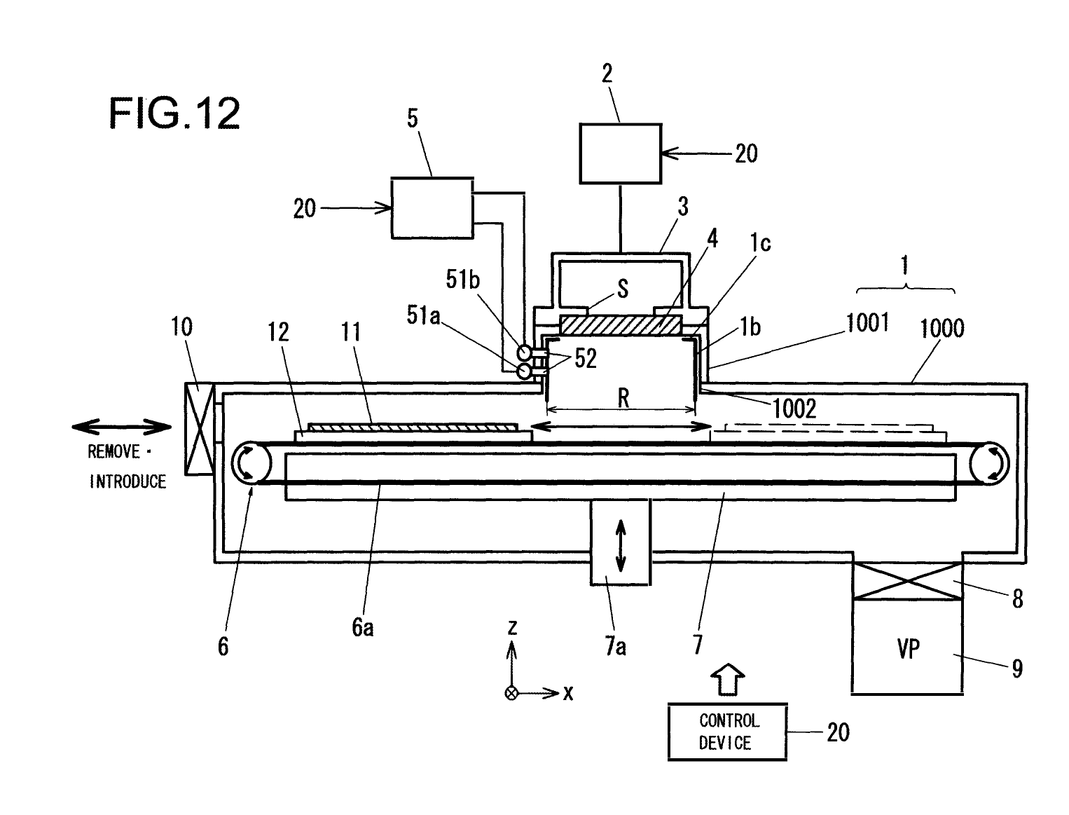

FIG. 12 is a figure for explanation of the third embodiment of the present invention, this being an improvement upon the surface wave plasma CVD device shown in FIGS. 10 and 11. FIG. 12 is a sectional view of this surface wave plasma CVD device as seen from the front. While no sectional view corresponding to FIG. 12 is provided, it should be understood that the shapes of the dielectric plate 4, the insulating shield member 1b, the gas supply conduits 51a and 51b, and the gas ejection portion 52 in FIG. 12 related to the Y direction are the same as those shown in FIG. 11. Moreover it should be understood that to structural elements of this apparatus of FIG. 12 that correspond to similar structural elements of the apparatus shown in FIGS. 10 and 11, the same reference symbols are appended, and that the following explanation will concentrate upon the portions that are different from those of the apparatus shown in FIGS. 10 and 11.

With the apparatus shown in FIG. 12, the vacuum chamber 1 consists of a first chamber 1000 in which the substrate moving device 6 is disposed, and a second chamber 1001 in which the dielectric plate 4, the gas ejection portions 52, and the insulating shield members 1b and 1c are disposed. The first chamber 1000 and the second chamber 1001 are connected via an opening 1002 so as to communicate with one another.

With the apparatus shown in FIG. 10, because of the existence of the mechanism that moves the substrate 11 to and fro in the X direction, the dimension in the X direction and the dimension in the Y direction of the substrate moving device 6 are quite large. On the other hand, as compared to the dimension in the X direction of the substrate moving device 6, the dimension in the X direction of the region in which the dielectric plate 4 and the insulating shield members 1b and 1c are disposed is significantly smaller. Due to this, by dividing the vacuum chamber 1 into the two chambers 1000 and 1001 according to the size of the structural elements that they are to contain, as in this third embodiment, it is possible to reduce the total volume of the vacuum chamber 1 as compared to the case of the apparatus shown in FIG. 10.

As a result, it may be expected that the load upon the vacuum pumping device 9 that evacuates the interior of the vacuum chamber 1 will be reduced. It should be understood that, while the gas ejection portions 52 are provided along the long side towards the downstream side of the direction of moving of the layer formation processing region R that is shaped as a rectangle, it would also be acceptable to provide them along the long side towards the upstream side of the direction of moving, or to provide them along both these long sides. This feature also is true for the case of the apparatus shown in FIG. 10.

### Embodiment #4

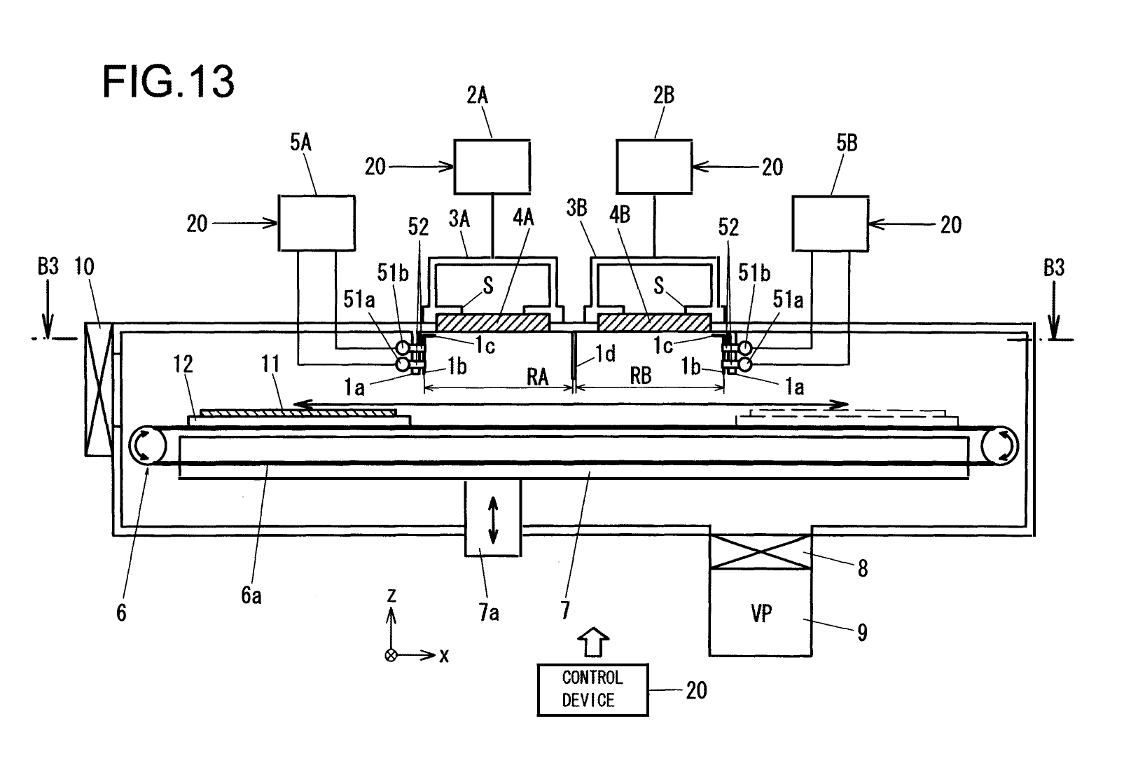

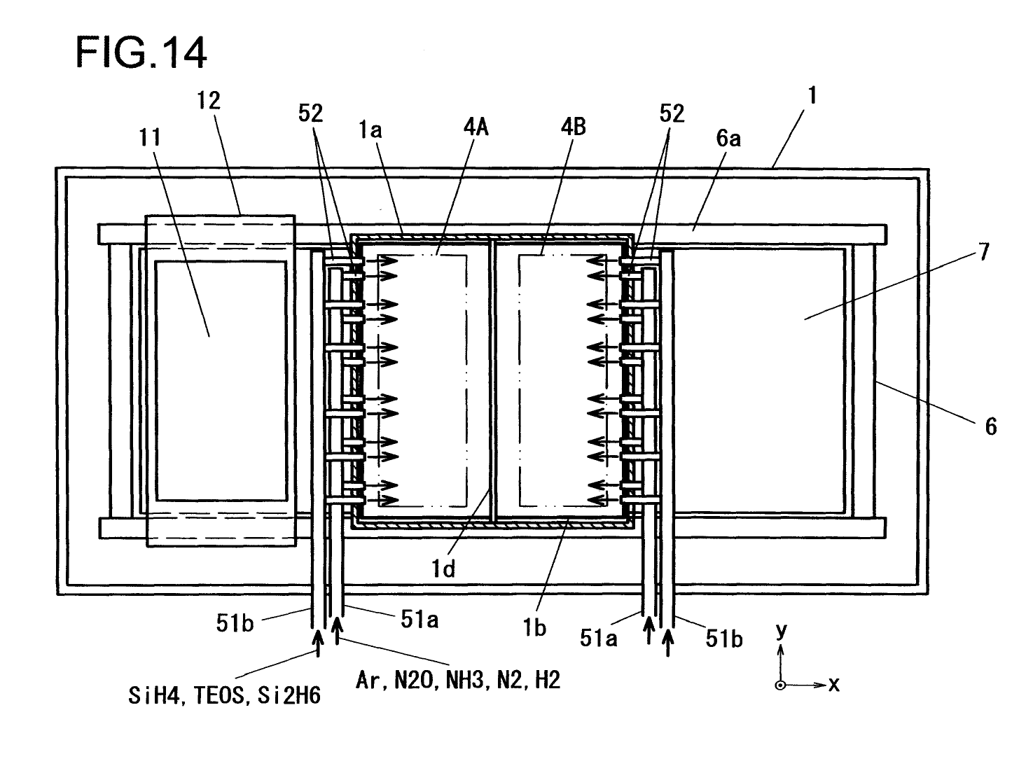

FIGS. 13 and 14 are figures for explanation of a fourth embodiment of the present invention, and show an apparatus that is a further improvement upon the surface wave plasma CVD device shown in FIGS. 10 and 11. FIG. 13 is a sectional view of the apparatus as seen from the front, while FIG. 14 is a sectional view thereof along the lines shown by the arrows B3-B3 in FIG. 13. In this embodiment, two layer formation processing regions RA and RB are formed by dividing the space surrounded by the insulating shield member lb into two spaces that are arranged side by side along the direction along which the substrate 11 is moved. In other words, two approximately rectangular dielectric plates 4A and 4B are arranged upon the upper surface of the vacuum chamber 1 with a gap being left between them, so that the long sides of these dielectric plates 4A and 4B are mutually adjacent. These dielectric plates 4A and 4B are arranged side by side along the direction in which the substrate 11 is moved (i.e. along the X direction). A waveguide 3A and a microwave output unit 2A are provided for the dielectric plate 4A, and a waveguide 3B and a microwave output unit 2B are provided for the dielectric plate 4B.

On the other hand, the insulating shield member 1b is arranged within the vacuum chamber 1 so as to surround the rectangular shape that is defined by the layer formation processing regions RA and RB that oppose the dielectric plates 4A and 4B respectively. This insulating shield member 1b is removably attached to the inner peripheral sides of the support member 1a that is formed in the shape of a rectangle, in other words they are attached to the sides of the support member 1a, facing the layer formation processing regions RA and RB. Moreover, a plasma shield member 1d that extends in the Y direction is provided within the vacuum chamber 1 between the dielectric plates 4A and 4B. This plasma shield member 1d is endowed with the function of acting as a dividing wall that separates the layer formation region that is defined in the region that opposes the dielectric plates 4A and 4B into the two layer formation processing regions RA and RB that are arranged side by side along the direction of to and fro motion of the substrate, and the member 1d also functions as a gas baffle. This plasma shield member 1d may be made from metal or the like, thus being an electrically conductive member, or may be made from an insulating material that is similar to the material employed for the insulating shield material 1b.

The supply of the gas for plasma generation and of the process material gas for layer formation to the layer formation processing region RA is performed by a gas supply device 5A. On the other hand, the supply of the gas for plasma generation and of the process material gas for layer formation to the layer formation processing region RB is performed by a gas supply device 5B that is separate from the gas supply device 5A. The injection of gas into the layer formation processing region RA is performed by a plurality of gas ejection portions 52 that are provided so as to extend along the part of the insulating shield member 1b that is arranged upon the long edge on the left side in the figure of the layer formation processing region 4A that is formed in a rectangular shape. On the other hand, the injection of gas into the layer formation processing region RB is performed by a plurality of gas ejection portions 52 that are provided so as to extend along the part of the insulating shield member 1b that is arranged upon the long edge on the right side in the figure of the layer formation processing region 4B that is formed in a rectangular shape.

Since, with the apparatus of this fourth embodiment, as shown in FIGS. 13 and 14, it is arranged to perform supply of gas to the layer formation processing regions 4A and 4B via the gas ejection portions 52 that are arranged both on the left side of the layer formation processing region 4A and also on the right side of the layer formation processing region 4B, accordingly it is possible to narrow down the gap between the layer formation processing region 4A and the layer formation processing region 4B as much as possible, and it becomes possible to arrange the two plasma sources (i.e. the layer processing regions 4A and 4B) in a side by side configuration close to one another.

Furthermore, it is possible to perform the control of the microwave output unit 2A and the gas supply device 5A that are related to the layer formation processing region RA and the control of the microwave output unit 2B and the gas supply device 5B that are related to the layer formation processing region RB separately. Due to this, it becomes possible to make the layer formation conditions when the substrate 11 passes through the layer formation processing region RA and the layer formation conditions when it passes through the layer formation processing region RB to be different from one another, so that it is possible to form two thin layers whose formation conditions differ from one another during a single moving episode of the substrate in one direction. Of course, it is also possible to perform layer formation in both these regions RA and RB under the same layer formation conditions, in which case it is possible to make the plasma source wider even without using dielectric plates of greater area, so that it may be expected that the time period for layer formation will be shortened by increasing the moving speed of the substrate 11.

It should be understood that, with the third and the fourth embodiments described above as well, the insulating shield member is provided in order to prevent reduction of the density of the plasma. However, while it is possible to omit the insulating shield member if it will not cause any problem even if there is some reduction of the density of the plasma, then, even if the insulating shield member is omitted in this manner, it will still be possible to obtain the beneficial operational effect described above by providing the two separate layer formation processing regions RA and RB and by controlling the layer formation conditions in these regions independently. In a similar manner, even if the insulating shield member in the third embodiment is omitted, it will still be possible to obtain the beneficial operational effect described above of reduction of the chamber volume.

While in the embodiments described above, as shown in FIGS. 1 and 10, layer formation was performed upon only one large substrate that was mounted upon the tray 12, it would also be acceptable to arrange to perform layer formation upon a plurality of smaller substrates that are all mounted together upon the tray 12. In this case, the range over which this plurality of smaller substrates are mounted would correspond to the same range for the subject of layer formation.

Furthermore, while it is arranged to perform introduction and removal of the substrate 11 via the gate valve 10 that is provided at the left side of the vacuum chamber 1, it would also be acceptable to use the gate valve 10 only for introduction of the substrate 11, and additionally to provide another gate valve dedicated to removal of the substrate 11 to the right side of the vacuum chamber 1 as seen in the figure. By providing this type of structure, it may be expected that the takt time for loading and unloading the substrate 11 could be shortened.

It should be understood that the insulating shield member 1b of the present invention that has been explained in the above description may be made as a plate shaped insulating member that can be detached. Moreover, it would also be acceptable to form a layer of insulating material by processing the surface of a metallic plate that is made from aluminum alloy or stainless steel alloy or the like, and to use this as the insulating shield member. In this case, it will be sufficient to form the layer of insulating material only upon the surface of the metallic plate on the side of the layer formation processing region, or, alternatively, not to form it upon this entire surface of the metallic plate. This is due to the fact that, provided that there is insulating material present upon the part of the surface of the metallic plate that contacts the plasma in the layer formation processing region, absorption of the electrons in the plasma will be prevented as previously described, so that reduction of the density of the plasma will be avoided. Types of surface coating processing that may be appropriate are, for example, formation of a layer of oxide by oxidization, formation of a layer of insulating material consisting of silicon oxide or silicon nitride or the like by a layer formation process, or application of an insulating material or the like. While in FIG. 4(a) the insulating shield member 1b is provided in a configuration such that it is somewhat separated from the dielectric plate 4, it would also be acceptable to provide it very close to the dielectric plate 4.

While various embodiments and variant embodiments have been explained in the above description, the present invention should not be considered as being limited by the details thereof. Moreover, the various embodiments described above may be employed either singly, or in any combination. This is because it is possible to reap the beneficial effects of each of the embodiments either singly or synergistically. Moreover, other modes of implementation that are considered to fall within the range of the technical concept of the present invention are also to be considered as being within the scope of the present invention.

The content of the disclosure of the following application, upon which priority is claimed, is hereby incorporated herein by reference:

1. A surface wave plasma CVD apparatus, comprising:
a waveguide that is connected to a microwave source, and in which a plurality of slot antennas are formed thereof;
a dielectric plate for conducting microwaves emitted from the plurality of slot antennas into a plasma processing chamber so that a surface wave plasma is produced;
an insulating shield member that is arranged so as to surround a layer formation processing region in which the surface wave plasma is produced; and
a gas ejection portion that ejects process material gas into the layer formation processing region.

2. A surface wave plasma CVD apparatus according to claim 1,
the insulating shield member being made from an insulating material shaped in a plate, and further comprising a support member that is arranged at an end portion of the layer formation processing region;
and wherein the insulating shield member is removably fitted to a side of the support member that faces towards the layer formation processing region.

3. (canceled)

4. A surface wave plasma CVD apparatus according to claim 2, wherein the insulating shield member is a thin metallic plate whose surface is coated with an insulating layer.

5. (canceled)

6. A surface wave plasma CVD apparatus according to claim 2, wherein the gas ejection portion is provided to the support member.

7. A surface wave plasma CVD apparatus according to claim 1, further comprising:
a moving device that performs a to and fro motion of a plate-shaped substrate that is to be a subject of layer formation so that the substrate that is to be a subject of layer formation passes through the layer formation processing region, and
a control device that controls the to and fro motion by the moving device of the substrate that is to be a subject of layer formation according to layer formation conditions
wherein a first waiting region and a second waiting region are provided within the plasma processing chamber on opposite sides of the layer formation processing region along a moving path of the substrate that is to be a subject of layer formation, and the moving device performs a to and fro motion of the substrate that is to be a subject of layer formation between the first waiting region and the second waiting region.

8. A surface wave plasma CVD apparatus according to claim 1, wherein the dielectric plate is approximately formed as a rectangle; and further comprising:
a plurality of gas ejection portions, provided along at least one long edge of the layer formation processing region, that eject process material gas into the layer formation region;
a moving device that performs a to and fro motion of a plate-shaped substrate that is to be a subject of layer formation in a direction orthogonal to the long sides of the layer formation processing region, so that the substrate that is to be a subject of layer formation passes through the layer formation processing region; and
a control device that controls the to and fro motion by the moving device of the substrate that is to be a subject of layer formation, according to conditions for layer formation.

9. A surface wave plasma CVD apparatus according to claim 1, wherein the dielectric plate consists of approximately rectangular first and second dielectric plates arranged side by side so that their long sides neighbor one another, and the insulating shield member is arranged so as to surround the layer formation processing region in a rectangular shape, and further comprising:
a moving device that performs a to and fro motion of a plate-shaped substrate that is to be a subject of layer formation in a direction orthogonal to the long sides of the layer formation processing region, so that the substrate that is to be a subject of layer formation passes through the layer formation processing region;
a dividing wall that is arranged between the first and second rectangular dielectric plates arranged side by side, and that divides the layer formation processing region into first and second divided regions arranged side by side along the direction of the to and fro motion;
a plurality of gas ejection portions, provided along respective long edges of the layer formation processing region, that eject process material gas into both the first and the second divided regions;
and
a control device that controls the to and fro motion by the moving device of the substrate that is to be a subject of layer formation, according to conditions for layer formation.

10. (canceled)

11. (canceled)

12. A surface wave plasma CVD apparatus according to claim 7, wherein a back plate that controls temperature of the substrate that is to be a subject of layer formation is disposed in a moving path of the substrate that is a subject of layer formation by the moving device.

13. (canceled)

14. A surface wave plasma CVD apparatus according to claim 1, further comprising a moving device that moves a film-shaped substrate that is to be the subject of layer formation so that it passes through the layer formation processing region, and a cylindrical back plate that controls the temperature of this subject of layer formation.

15. A surface wave plasma CVD apparatus according to claim 14, wherein the cylindrical back plate supports the film-shaped substrate in a region that opposes the dielectric plate, and the moving device performs a to and fro motion of the film-shaped substrate over a predetermined section so as to perform layer formation in multiple layers.

16. (canceled)

17. A method for forming a layer upon the subject of layer formation with a surface wave plasma CVD apparatus according to claim 7, wherein thin layers are formed under different layer formation conditions for outward and return paths of the to and fro motion, and formation of a thin layer is performed by the layers formed under different layer formation conditions being laminated together.

18. A surface wave plasma CVD apparatus according to claim 2, wherein the dielectric plate is approximately formed as a rectangle; and further comprising:
a plurality of gas ejection portions, provided along at least one long edge of the layer formation processing region, that eject process material gas into the layer formation region;
a moving device that performs a to and fro motion of a plate-shaped substrate that is to be a subject of layer formation in a direction orthogonal to the long sides of the layer formation processing region, so that the substrate that is to be a subject of layer formation passes through the layer formation processing region; and
a control device that controls the to and fro motion by the moving device of the substrate that is to be a subject of layer formation, according to conditions for layer formation.

19. A surface wave plasma CVD apparatus according to claim 2, wherein the dielectric plate consists of approximately rectangular first and second dielectric plates arranged side by side so that their long sides neighbor one another, and the insulating shield member is arranged so as to surround the layer formation processing region in a rectangular shape, and further comprising:
a moving device that performs a to and fro motion of a plate-shaped substrate that is to be a subject of layer formation in a direction orthogonal to the long sides of the layer formation processing region, so that the substrate that is to be a subject of layer formation passes through the layer formation processing region;
a dividing wall that is arranged between the first and second rectangular dielectric plates arranged side by side, and that divides the layer formation processing region into first and second divided regions arranged side by side along the direction of the to and fro motion;
a plurality of gas ejection portions, provided along respective long edges of the layer formation processing region, that eject process material gas into both the first and the second divided regions; and
a control device that controls the to and fro motion by the moving device of the substrate that is to be a subject of layer formation, according to conditions for layer formation.

20. A surface wave plasma CVD apparatus according to claim 8, wherein a back plate that controls temperature of the substrate that is to be a subject of layer formation is disposed in a moving path of the substrate that is a subject of layer formation by the moving device.

21. A surface wave plasma CVD apparatus according to claim 9, wherein a back plate that controls temperature of the substrate that is to be a subject of layer formation is disposed in a moving path of the substrate that is a subject of layer formation by the moving device.
